(19) United States
(12) Patent Application Publication
(10) Pub. No.: US 2026/0047061 A1
(43) Pub. Date: Feb. 12, 2026

(54) THIN FILM TRANSISTOR, MEMORY, AND ELECTRONIC DEVICE

(71) Applicant: HUAWEI TECHNOLOGIES CO., LTD., Shenzhen (CN)

(72) Inventors: Kailiang Huang, Shenzhen (CN); Weiliang Jing, Shanghai (CN); Ying Sun, Shenzhen (CN); Zhengbo Wang, Shenzhen (CN)

(73) Assignee: HUAWEI TECHNOLOGIES CO., LTD., Shenzhen (CN)

(21) Appl. No.: 19/360,361

(22) Filed: Oct. 16, 2025

Related U.S. Application Data
(63) Continuation of application No. PCT/CN2023/138906, filed on Dec. 14, 2023.

(30) Foreign Application Priority Data
Apr. 18, 2023 (CN) 202310424651.2

(51) Int. Cl. H10B 12/00

(52) U.S. Cl. CPC H10B 12/00

(57) ABSTRACT

Examples of a thin film transistor and a memory are described. One example thin film transistor includes a first electrode, a gate, a gate dielectric layer, a channel layer, and a second electrode. The gate includes a gate base and a gate pillar. The gate base is located on the first electrode, and the gate pillar is located between the gate base and the first electrode. The gate dielectric layer is located between the first electrode and the gate pillar. The channel layer is at least partially located between the first electrode and the gate base. The second electrode is located between the first electrode and the gate base, and is located on a side that is of the channel layer and that is away from the gate pillar. Both the second electrode and the first electrode are in contact with the channel layer.

### CROSS-REFERENCE TO RELATED APPLICATIONS

This application is a continuation of International Application No. PCT/CN2023/138906, filed on Dec. 14, 2023, which claims priority to Chinese Patent Application No. 202310424651.2, filed on Apr. 18, 2023. The disclosures of the aforementioned applications are hereby incorporated by reference in their entireties.

### TECHNICAL FIELD

This application relates to the field of semiconductor technologies, and in particular, to a thin film transistor, a memory, and an electronic device.

### BACKGROUND

With development of science and technology, various types of memories emerge. In the various types of memories, a gain cell memory (a memory for short below) is widely used, to mainly implement high-speed read/write and high-density integration. A memory of a 2T0C structure can achieve a nanosecond-level read/write speed and a millisecond-level storage time.

Currently, a thin film transistor (TFT) is usually used as a transistor in the memory, to reduce dynamic power consumption of the memory due to an advantage of ultra-low electric leakage of the TFT.

However, as a size of the TFT is continuously reduced, a contact area between a source/drain and a channel layer of the TFT is continuously reduced. As a result, a contact resistance is gradually increased, an on-state current of the TFT is affected, and it is difficult to further meet requirements for a high storage density and a high read speed of the memory.

### SUMMARY

Embodiments of this application provide a thin film transistor, a memory, and an electronic device, to reduce a contact resistance of the thin film transistor, increase an on-state current of the thin film transistor, and increase a read/write speed of the memory.

To achieve the foregoing objectives, the following technical solutions are used in embodiments of this application.

According to a first aspect, a thin film transistor is provided. The thin film transistor includes a first electrode, a gate, a gate dielectric layer, a channel layer, and a second electrode. The gate includes a gate base and a gate pillar in contact with the gate base. The gate base is located on the first electrode, and the gate pillar is located between the gate base and the first electrode. The gate dielectric layer is located between the first electrode and the gate pillar, and is in contact with a side surface of the gate pillar. The channel layer is at least partially located between the first electrode and the gate base, and is located on a side that is of the gate dielectric layer and that is away from the gate pillar. The second electrode is located between the first electrode and the gate base, and is located on a side that is of the channel layer and that is away from the gate pillar. Both the second electrode and the first electrode are in contact with the channel layer. The channel layer has a first surface and a second surface, the first surface is in contact with the first electrode and the second electrode, and the second surface is in contact with the gate dielectric layer. Conductivities of the channel layer are gradually decreased in a direction from the first surface to the second surface.

The thin film transistor provided in some embodiments of this application has a three-dimensional structure as a whole. The first electrode, the second electrode, and the gate base of the gate of the thin film transistor are sequentially arranged in a vertical direction, so that the gate pillar of the gate passes through the second electrode, and points to the first electrode. In addition, the gate dielectric layer and the channel layer are sequentially disposed between the gate pillar and the first electrode and between the gate pillar and the second electrode, so that the thin film transistor can form a thin film transistor of a vertical channel structure. An orthographic projection area of the thin film transistor on a reference plane is basically equal to an orthographic projection area of the first electrode on the reference plane. Compared with a transistor of a planar structure, the thin film transistor provided in this embodiment of this application has a smaller orthographic projection area on the reference plane. This can effectively increase area utilization of the thin film transistor.

In addition, the conductivity of the channel layer is gradually decreased in the direction from the first surface to the second surface by setting the conductivity of the channel layer. This can effectively improve efficiency of injecting a charge carrier into the channel layer, reduce a contact resistance between the first electrode and the channel layer, reduce a contact resistance between the second electrode and the channel layer, and increase an on-state current of the thin film transistor.

In addition, when the thin film transistor is used in the memory, not only an area occupied by a memory cell based on the thin film transistor can be greatly reduced, a storage density can be greatly increased, but also a read/write speed of the memory cell based on the thin film transistor can be increased.

In a possible implementation of the first aspect, the channel layer is doped with a metal element, and a proportion of the metal element doped in the channel layer is gradually decreased in the direction from the first surface of the channel layer to the second surface of the channel layer. This can ensure that the conductivity is gradually decreased in the direction from the first surface of the channel layer to the second surface of the channel layer, to ensure effect of increasing a contact resistance and an on-state current of the thin film transistor.

In a possible implementation of the first aspect, a material of the channel layer includes indium gallium zinc oxide, and the metal element includes indium. In a possible implementation of the first aspect, the channel layer includes a primary channel layer and a back channel layer that are sequentially stacked in a direction away from the gate pillar. A conductivity of the primary channel layer is less than a conductivity of the back channel layer. The back channel layer may be used as a primary film for charge carrier transmission, and the back channel layer may be used to reduce a contact resistance between the channel layer and the first electrode and a contact resistance between the channel layer and the second electrode, and increase the on-state current of the thin film transistor. In addition, the primary channel layer is used as a secondary film for charge carrier transmission, and the primary channel layer may be used to ensure a semiconductor channel characteristic of the channel layer.

In a possible implementation of the first aspect, each of the primary channel layer and the back channel layer is doped with a metal element. A proportion of the metal element doped in the primary channel layer is less than a proportion of the metal element doped in the back channel layer. This can ensure that the conductivity of the primary channel layer is less than the conductivity of the back channel layer, to ensure effect of increasing the contact resistance and the on-state current of the thin film transistor.

In a possible implementation of the first aspect, a material of each of the primary channel layer and the back channel layer includes indium gallium zinc oxide, and the metal element doped in each of the primary channel layer and the back channel layer includes indium. In a possible implementation of the first aspect, the channel layer further includes an interface layer located between the gate pillar and the primary channel layer. A conductivity of the interface layer is less than a conductivity of the primary channel layer. This can further reduce conductive performance of the film in contact with the gate dielectric layer, to further ensure a semiconductor channel characteristic of the channel layer.

In a possible implementation of the first aspect, the interface layer is doped with a metal element. A proportion of the metal element doped in the interface layer is less than a proportion of a metal element doped in the primary channel layer. This can ensure that a conductivity of the interface layer is less than a conductivity of the primary channel layer, to ensure effect of increasing the contact resistance and the on-state current of the thin film transistor.

In a possible implementation of the first aspect, a material of the interface layer includes indium gallium zinc oxide, and the metal element doped in the interface layer includes indium.

In a possible implementation of the first aspect, a work function of the interface layer is less than a work function of the primary channel layer; and/or an electron affinity of the interface layer is less than an electron affinity of the primary channel layer. In this way, the interface layer may be used to push the charge carrier in the channel layer away from a side surface that is of the interface layer and that is in contact with the gate dielectric layer, to reduce a scattering probability of the charge carrier, increase effective mobility of the thin film transistor, and increase an on-state current of the thin film transistor. The interface layer is disposed, so that a risk of scattering of the charge carrier can be effectively reduced when a size of the thin film transistor is reduced and thicknesses of different films in the channel layer are reduced.

In a possible implementation of the first aspect, a work function of the primary channel layer is less than a work function of the back channel layer; and/or an electron affinity of the primary channel layer is less than an electron affinity of the back channel layer. This can ensure that concentration of a charge carrier in the back channel layer is greater than concentration of a charge carrier in the primary channel layer, to ensure reduction of a contact resistance between the back channel layer and the first electrode and a contact resistance between the back channel layer and the second electrode and increase of the on-state current of the thin film transistor.

In a possible implementation of the first aspect, in the direction from the first surface of the channel layer to the second surface of the channel layer, a work function of the channel layer is gradually decreased, and/or an electron affinity of the channel layer is gradually decreased. This can improve efficiency of injecting the charge carrier into the channel layer, reduce the contact resistance between the first electrode and the channel layer, reduce the contact resistance between the second electrode and the channel layer, and increase the on-state current of the thin film transistor, and can further ensure that the channel layer has a good semiconductor channel characteristic.

In a possible implementation of the first aspect, the thin film transistor further includes a first ohmic contact layer and a second ohmic contact layer. The first ohmic contact layer is located on a surface of a side that is of the first electrode and that is close to the second electrode, and is in contact with the channel layer. The second ohmic contact layer is located on a surface of a side that is of the second electrode and that is close to the first electrode, and is in contact with the channel layer. The first ohmic contact layer is configured to reduce the contact resistance between the first electrode and the channel layer, and the second ohmic contact layer is configured to reduce the contact resistance between the second electrode and the channel layer. This helps improve performance of the thin film transistor and increase the on-state current of the thin film transistor.

In a possible implementation of the first aspect, a part that is of the gate dielectric layer and that is located between the first electrode and the gate base surrounds the gate pillar; and the channel layer surrounds the gate pillar. In this case, the thin film transistor forms a vertical channel-all-around thin film transistor. This is equivalent to increasing an effective channel width of the channel layer. This helps further increase the on-state current of the thin film transistor, and further increase the read/write speed of the memory cell based on the thin film transistor.

In a possible implementation of the first aspect, the channel layer is further located between the first electrode and the gate pillar, and is in contact with a surface of a side that is of the gate dielectric layer and that is close to the first electrode. This helps increase the contact area between the first electrode and the channel layer, and helps further reduce the contact resistance between the first electrode and the channel layer.

In a possible implementation of the first aspect, a groove is disposed on a side that is of the first electrode and that is close to the gate, and the channel layer extends into the groove. This helps further increase the contact area between the first electrode and the channel layer, and helps further reduce the contact resistance between the first electrode and the channel layer.

According to a second aspect, a thin film transistor is provided. The thin film transistor includes a first electrode, a gate, a gate dielectric layer, a channel layer, and a second electrode. The gate includes a gate base and a gate pillar in contact with the gate base. The gate base is located on the first electrode, and the gate pillar is located between the gate base and the first electrode. The gate dielectric layer is located between the first electrode and the gate pillar, and is in contact with a side surface of the gate pillar. The channel layer is at least partially located between the first electrode and the gate base, and is located on a side that is of the gate dielectric layer and that is away from the gate pillar. A groove is disposed on a side that is of the first electrode and that is close to the gate, and the channel layer extends into the groove. The second electrode is located between the first electrode and the gate base, and is located on a side that is of the channel layer and that is away from the gate pillar. Both the second electrode and the first electrode are in contact with the channel layer. The channel layer includes a first sub-part, a second sub-part, and a third sub-part, where the first sub-part is in contact with the first electrode, the second sub-part is in contact with the second electrode, and the first sub-part and the second sub-part are located at two opposite ends of the third sub-part, and are both in contact with the third sub-part. Resistances of the first sub-part and the second sub-part are both less than a resistance of the third sub-part.

The thin film transistor provided in some embodiments of this application has a three-dimensional structure as a whole. Compared with a transistor of a planar structure, the thin film transistor provided in this embodiment of this application has a smaller orthographic projection area on the reference plane. This can effectively increase area utilization of the thin film transistor.

The channel layer is divided, so that resistances of different parts are different. This can effectively reduce a contact resistance between the first electrode and the channel layer, and reduce a contact resistance between the second electrode and the channel layer, thereby increasing an on-state current of the thin film transistor. When the thin film transistor is used in a memory, not only an area occupied by a memory cell based on the thin film transistor can be greatly reduced, a storage density can be greatly increased, but also a read/write speed of the memory cell based on the thin film transistor can be increased.

In a possible implementation of the second aspect, the channel layer is doped with hydrogen. Content of hydrogen in the first sub-part and content of hydrogen in the second sub-part are both greater than content of hydrogen in the third sub-part. This can ensure that the resistances of the first sub-part and the second sub-part are both less than the resistance of the third sub-part, to ensure that there is a low contact resistance between the first electrode and the channel layer, and ensure that there is a low contact resistance between the second electrode and the channel layer.

In a possible implementation of the second aspect, the thin film transistor further includes a first ohmic contact layer and a second ohmic contact layer. The first ohmic contact layer is located on a surface of a side that is of the first electrode and that is close to the second electrode, and is in contact with the channel layer. The second ohmic contact layer is located on a surface of a side that is of the second electrode and that is close to the first electrode, and is in contact with the channel layer. The first ohmic contact layer is configured to reduce a contact resistance between the first electrode and the channel layer, and the second ohmic contact layer is configured to reduce a contact resistance between the second electrode and the channel layer. This helps improve performance of the thin film transistor and increase the on-state current of the thin film transistor.

In a possible implementation of the second aspect, a part that is of the gate dielectric layer and that is located between the first electrode and the gate base surrounds the gate pillar; and the channel layer surrounds the gate pillar. This is equivalent to increasing an effective channel width of the channel layer. This helps further increase the on-state current of the thin film transistor, and further increase the read/write speed of the memory cell based on the thin film transistor.

In a possible implementation of the second aspect, the channel layer is further located between the first electrode and the gate pillar, and is in contact with a surface of a side that is of the gate dielectric layer and that is close to the first electrode. This helps increase a contact area between the first electrode and the channel layer, and helps further reduce the contact resistance between the first electrode and the channel layer.

According to a third aspect, a memory is provided. The memory includes a substrate and at least one layer of memory array located on the substrate. Each layer of memory array includes a plurality of memory cells. The memory cell includes a first thin film transistor and a second thin film transistor located on the first thin film transistor. A gate of the first thin film transistor is electrically connected to a first electrode of the second thin film transistor. At least one of the first thin film transistor and the second thin film transistor is the thin film transistor in any one of the implementations of the first aspect, or is the thin film transistor in any one of the implementations of the second aspect.

The memory provided in some embodiments of this application uses the thin film transistor in any one of the implementations of the first aspect or the thin film transistor in any one of the implementations of the second aspect, to form a memory cell. In this way, an area occupied by the memory cell on the substrate can be reduced. For example, an area of each memory cell may be reduced to 4F2. Further, a storage density of the memory can be effectively increased. In addition, because the thin film transistor has a high on-state current, read/write speeds of the memory cell and the memory can be effectively increased.

In a possible implementation of the third aspect, each layer of memory array further includes a plurality of write word lines, a plurality of write bit lines, a plurality of read word lines, and a plurality of read bit lines. A first electrode of the first thin film transistor is electrically connected to the read word line, a second electrode of the first thin film transistor is electrically connected to the read bit line, a second electrode of the second thin film transistor is electrically connected to the write bit line, and a gate of the second thin film transistor is electrically connected to the write word line.

In a possible implementation of the third aspect, the memory further includes an integrated circuit. The integrated circuit is electrically connected to the at least one layer of memory array. In this way, the memory array can be controlled, through the integrated circuit, to store data.

According to a fourth aspect, an electronic device is provided. The electronic device includes a circuit board and a memory, and the memory is electrically connected to the circuit board. The memory is the memory in any one of implementations of the third aspect.

For technical effect achieved in any design of the fourth aspect, refer to technical effect achieved in different designs of third aspect. Details are not described herein again.

### BRIEF DESCRIPTION OF DRAWINGS

FIG. 1 is a diagram of a structure of an electronic device according to an embodiment of this application;

FIG. 2 is a diagram of an equivalent circuit of a memory cell according to an embodiment of this application;

FIG. 3 is a sectional view of a thin film transistor according to an embodiment of this application;

FIG. 4 is a sectional view of another thin film transistor according to an embodiment of this application;

FIG. 5 is a sectional view of a channel layer in the thin film transistor shown in FIG. 4;

FIG. 6 is a sectional view of still another thin film transistor according to an embodiment of this application;

FIG. 7a is a sectional view of the thin film transistor shown in FIG. 6 in a C-C direction;

FIG. 7b is another sectional view of the thin film transistor shown in FIG. 6 in a C-C direction;

FIG. 7c is still another sectional view of the thin film transistor shown in FIG. 6 in a C-C direction;

FIG. 8 is a sectional view of yet another thin film transistor according to an embodiment of this application;

FIG. 9 is a sectional view of still yet another thin film transistor according to an embodiment of this application;

FIG. 10 is a sectional view of a further thin film transistor according to an embodiment of this application;

FIG. 11 is a sectional view of a still further thin film transistor according to an embodiment of this application;

FIG. 12 is a sectional view of a yet further thin film transistor according to an embodiment of this application;

FIG. 13 is a diagram of a structure of repairing a channel layer according to an embodiment of this application;

FIG. 14 is a diagram of a structure of a memory according to an embodiment of this application;

FIG. 15 is a diagram of a structure of another memory according to an embodiment of this application;

FIG. 16 is a diagram of an equivalent circuit of a memory array according to an embodiment of this application;

FIG. 17 is a diagram of a three-dimensional structure of a memory according to an embodiment of this application;

FIG. 18 is a sectional view of a memory array according to an embodiment of this application; and

FIG. 19 is a sectional view of another memory array according to an embodiment of this application.

### DESCRIPTION OF EMBODIMENTS

The following describes technical solutions in embodiments of this application with reference to accompanying drawings in embodiments of this application. It is clear that the described embodiments are merely some but not all of embodiments of this application. All other embodiments obtained by a person of ordinary skill in the art based on embodiments of this application fall within the protection scope of this application.

In descriptions of embodiments of this application, “a plurality of” means two or more than two, unless otherwise specified. “At least one item (piece)” or a similar expression thereof indicates any combination of these items, including a single item (piece) or any combination of a plurality of items (pieces). For example, at least one item (piece) of a, b, and c may represent a, b, c, a-b, a-c, b-c, or a-b-c, where a, b, and c may be singular or plural.

The term “and/or” describes an association relationship between associated objects, and indicates that three relationships may exist. For example, a and/or b may indicate the following cases: Only a exists, both a and b exist, and only b exists, where a and b may be singular or plural. A character “/” generally indicates an “or” relationship between associated objects.

In addition, to clearly describe the technical solutions in embodiments of this application, terms such as “first” and “second” are used in embodiments of this application to distinguish between same items or similar items that provide basically same functions or purposes. A person skilled in the art may understand that the terms such as “first” and “second” do not limit a quantity or an execution sequence, and the terms such as “first” and “second” do not indicate a definite difference. In addition, in embodiments of this application, the word such as “example” or “for example” is used to represent giving an example, an illustration, or a description. Any embodiment or design scheme described as an “example” or “for example” in embodiments of this application should not be explained as being more preferred or having more advantages than another embodiment or design scheme. Exactly, use of the word such as “example” or “for example” is intended to present a related concept in a specific manner for ease of understanding.

In the description of some embodiments, expressions of “connection” and extensions thereof are used. The term “connection” should be understood in a broad sense. For example, the “connection” may be a fixed connection, a detachable connection, or an integral connection, or may be a direct connection or an indirect connection implemented through an intermediate medium. The term “contact” should be understood in a broad sense. For example, “contact” may be direct contact, or may be indirect contact through an intermediate medium. In addition, use of “based on” means openness and inclusiveness, since processes, steps, calculation, or other actions “based on” one or more of conditions or values may be based in practice on additional conditions or values outside the described values.

In embodiments of this application, “up”, “down”, “left”, and “right” are not limited to definitions relative to orientations in which components are schematically placed in accompanying drawings. It should be understood that these directional terms may be relative concepts used for relative description and clarification, and may change correspondingly based on a change of an orientation in which a component in an accompanying drawing is placed. In the accompanying drawings, for clarity, thicknesses of layers and regions are exaggerated, and a size proportion relationship between parts in the figures does not reflect an actual size proportion relationship. Thus, a change in a shape in the accompanying drawings due to, for example, manufacturing techniques and/or tolerances may be envisaged. Therefore, example implementations should not be construed as being limited to a shape of a region shown in this application, but rather include shape deviations due to, for example, manufacturing. For example, an etching region shown as a rectangle typically has a bending characteristic. Therefore, the regions shown in the accompanying drawings are essentially examples, and their shapes are not intended to show actual shapes of regions of a device, and are not intended to limit a scope of the example implementations.

In addition, an architecture and a scenario described in embodiments of this application are intended to describe the technical solutions in embodiments of this application more clearly, and do not constitute a limitation on the technical solutions provided in embodiments of this application. A person of ordinary skill in the art may know that with evolution of the architecture and emergence of new scenarios, the technical solutions provided in embodiments of this application are also applicable to similar technical problems.

An embodiment of this application provides an electronic device. The electronic device may be a mobile phone, a tablet computer (pad), a television, a desktop computer, a laptop computer, a handheld computer, a notebook computer, an ultra-mobile personal computer (UMPC), a netbook, a cellular phone, a personal digital assistant (PDA), an augmented reality (AR) device, a virtual reality (VR) device, an artificial intelligence (AI) device, a smart wearable device (for example, a smartwatch and a smart band), an in-vehicle device, a smart home device, and/or a smart city device, and a specific type of the electronic device is not specifically limited in embodiments of this application.

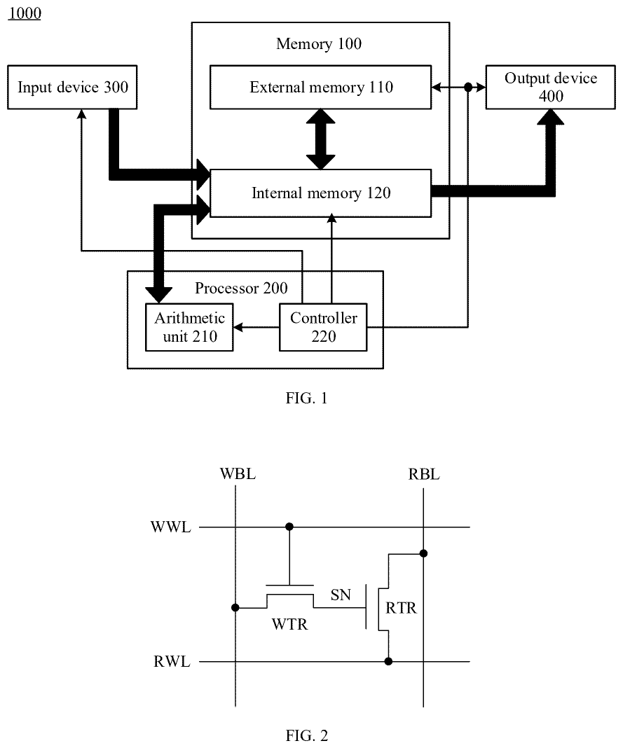

FIG. 1 is a diagram of an architecture of an electronic device according to an embodiment of this application. As shown in FIG. 1, the electronic device 1000 includes components such as a memory 100, a processor 200, an input device 300, and an output device 400. A person skilled in the art may understand that a structure of the electronic device shown in FIG. 1 does not constitute any limitation on the electronic device 1000, and the electronic device 1000 may include more or fewer components than those shown in FIG. 1, or may combine some of the components shown in FIG. 1, or may have a different component arrangement from that shown in FIG. 1.

The memory 100 is configured to store a software program and a module. The memory 100 mainly includes a program storage region and a data storage region. The program storage region may store an operating system, an application required by at least one function (such as a sound playing function and an image playing function), and the like. The data storage region may store data (such as audio data, image data, and a phone book) created based on use of the electronic device, and the like. In addition, the memory 100 includes an external memory 110 and an internal memory 120. Data stored in the external memory 110 and the internal memory 120 may be transmitted to each other. The external memory 110 includes, for example, a hard disk, a USB flash drive, and a floppy disk. The internal memory 120 includes, for example, a static random access memory (SRAM), a dynamic random access memory (DRAM), a read-only memory, and the like.

The processor 200 is a control center of the electronic device 1000, and connects various parts of the entire electronic device 1000 through various interfaces and lines. By running or executing the software program and/or the module that are stored in the memory 100, and invoking data stored in the memory 100, the processor 200 performs various functions of the electronic device 1000 and processes data, to perform overall monitoring on the electronic device 1000. Optionally, the processor 200 may include one or more processing units. For example, the processor 200 may include a central processing unit (CPU), an artificial intelligence (AI) processor, a digital signal processor (DSP), and a neural-network processing unit, or may be another application-specific integrated circuit (ASIC). In FIG. 1, an example in which the processor 200 is a CPU is used, and the CPU may include an arithmetic unit 210 and a controller 220. The arithmetic unit 210 obtains data stored in the internal memory 120, and processes the data stored in the internal memory 120. A processing result is usually sent back to the internal memory 120. The controller 220 may control the arithmetic unit 210 to process the data, and the controller 220 may further control the external memory 110 and the internal memory 120 to store data or read data. The memory 100 may store data generated by the processor 200.

The input device 300 is configured to receive input number or character information, and generate key signal input related to user settings and function control of the electronic device 1000. For example, the input device 300 may include a touchscreen and another input device. The touchscreen, also referred to as a touch panel, may collect a touch operation performed by a user on the touchscreen or near the touchscreen (for example, an operation performed by the user on the touchscreen or near the touchscreen by using any proper object or accessory such as a finger or a stylus), and drive a corresponding connection apparatus based on a preset program. Optionally, the touchscreen may include two parts: a touch detection apparatus and a touch controller. The touch detection apparatus detects a touch orientation of the user, detects a signal brought by the touch operation, and transfers the signal to the touch controller. The touch controller receives touch information from the touch detection apparatus, converts the touch information into touch point coordinates, sends the touch point coordinates to the processor 200, and can receive and execute a command sent by the processor 200. In addition, the touchscreen may be implemented in a plurality of types, such as a resistive type, a capacitive type, an infrared ray type, and a surface acoustic wave type. The another input device may include but is not limited to one or more of a physical keyboard, a function key (such as a volume control key or a power on/off key), a trackball, a mouse, a joystick, or the like. The controller 220 in the processor 200 may further control the input device 300 to receive an input signal or not to receive an input signal. In addition, the input number or character information received by the input device 300 and the key signal input related to user settings and function control of the electronic device may be stored in the internal memory 120.

The output device 400 is configured to output a signal corresponding to data that is input by the input device 300 and stored in the internal memory 120. For example, the output device 400 outputs a sound signal or a video signal. The controller 220 in the processor 200 may further control the output device 400 to output a signal or not to output a signal.

It should be noted that a thick arrow in FIG. 1 indicates data transmission, and a direction of the thick arrow indicates a data transmission direction. For example, a unidirectional arrow between the input device 300 and the internal memory 120 indicates that data received by the input device 300 is transmitted to the internal memory 120. For another example, a bidirectional arrow between the arithmetic unit 210 and the internal memory 120 indicates that the data stored in the internal memory 120 may be transmitted to the arithmetic unit 210, and data processed by the arithmetic unit 210 may be transmitted to the internal memory 120. A thin arrow in FIG. 1 indicates a component that can be controlled by the controller 220. For example, the controller 220 may control the external memory 110, the internal memory 120, the arithmetic unit 210, the input device 300, the output device 400, and the like.

Optionally, the electronic device 1000 shown in FIG. 1 may further include various sensors, for example, a gyroscope sensor, a hygrometer sensor, an infrared sensor, and a magnetometer sensor. Details are not described herein. Optionally, the electronic device 1000 may further include a wireless fidelity (Wi-Fi) module, a Bluetooth module, and the like. Details are not described herein.

It may be understood that, with development of internet technologies and cloud computing technologies, the information era is rapidly transitioning to the big data era, and a requirement for a storage system is continuously increasing. However, with development of Moore's Law, a gap between the processor and the memory becomes larger, and a growth rate of the processor far exceeds a growth rate of the memory. As a result, a storage density and a read/write speed of the memory cannot keep up with a computing speed of the processor, a “memory wall” phenomenon occurs, and overall performance of a system including the memory and the processor is limited.

To resolve the foregoing problem, a plurality of types of memories are proposed in recent years. A memory of a 2T0C structure is used as an example. The memory can implement a nanosecond-level read/write speed and a millisecond-level storage time, and occupies only one third of an area of the SRAM.

The memory of the 2T0C structure includes a plurality of memory cells, and each memory cell (that is, the 2T0C structure) includes two transistors. For example, FIG. 2 shows a memory cell in a memory of a 2T0C structure. As shown in FIG. 2, the memory cell includes a first transistor RTR and a second transistor WTR. The first transistor RTR may also be referred to as a read transistor, and the second transistor WTR may also be referred to as a write transistor.

Still refer to FIG. 2. A gate of the second transistor WTR is electrically connected to a write word line WWL, a drain of the second transistor WTR is electrically connected to a write bit line WBL, a source of the second transistor WTR is electrically connected to a gate of the first transistor RTR, a drain of the first transistor RTR is electrically connected to a read word line RWL, and a source of the first transistor RTR is electrically connected to a read bit line RBL. The source of the second transistor WTR and the gate of the first transistor RTR form a storage node SN.

An operating principle of the memory cell is as follows: First, in a “write” operation, the second transistor WTR is turned on under control of an electrical signal provided by the write word line WWL, and transmits an electrical signal provided by the write bit line WBL to the gate of the first transistor RTR, so that a potential of the gate of the first transistor RTR is synchronized with a potential of the electrical signal provided by the write bit line WBL, to implement writing of “0” and “1”. Then, the second transistor WTR is turned off under control of the electrical signal provided by the write word line WWL, and the potential of the gate of the first transistor RTR is determined based on electricity stored in the storage node SN. In a “read” operation, the read word line RWL provides an electrical signal, and logical information stored in the storage node SN is determined based on a magnitude of a current on the read bit line RBL.

In an actual application process of the memory of the 2T0C structure, an electric leakage phenomenon exists inside the memory cell (for example, electricity on the gate of the first transistor RTR leaks through the second transistor WTR). As a result, refreshing needs to be performed periodically to maintain data integrity, resulting in high dynamic power consumption.

To prolong retention duration of the memory of the 2T0C structure and resolve a problem of high power consumption of the memory of the 2T0C structure, currently, the memory of the 2T0C structure may be manufactured based on a TFT. An advantage of ultra-low electric leakage of the TFT can greatly prolong the retention duration of the memory of the 2T0C structure, thereby reducing dynamic power consumption. In addition, due to advantages such as a low temperature of a TFT manufacturing process and compatibility with a conventional microelectronics process, the memory cell may be used in a back end of line (BEOL) process, to implement heterogeneous integration and stacking integration, and increase a storage density.

However, a current TFT is basically a TFT of a planar structure, and therefore has a large planar size and a low area utilization rate. In addition, multi-layer routing needs to be performed, a manufacturing process is complex, and it is difficult to implement high-density storage. In addition, as a size of the TFT is continuously reduced, a contact area between a source/drain and a channel layer of the TFT is continuously reduced. As a result, a contact resistance is gradually increased, an on-state current of the TFT is affected, and it is difficult to further meet requirements for a high storage density and a high read speed of the memory.

In view of this, some embodiments of this application provide a thin film transistor and a memory in which the thin film transistor is used. The memory is, for example, a memory of a 2T0C structure. The memory may be used as the memory 100 in the electronic device 1000. For example, the memory provided in embodiments of this application may be used as the external memory 110 in the memory 100, or may be used as the internal memory 120 in the memory 100. The following schematically describes the thin film transistor and the memory in which the thin film transistor is used with reference to accompanying drawings.

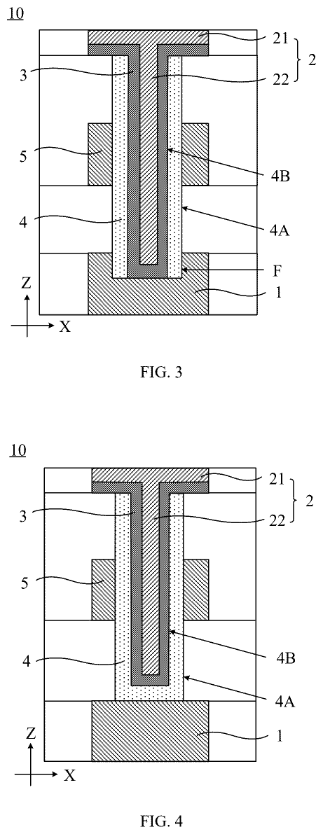

Each of FIG. 3 and FIG. 4 shows a cross-sectional structure of a thin film transistor. The thin film transistor may be an N-type transistor, or may be a P-type transistor.

With reference to FIG. 3 and FIG. 4, the thin film transistor 10 includes a first electrode 1, a gate 2, a gate dielectric layer 3, a channel layer 4, and a second electrode 5. One of the first electrode 1 and the second electrode 5 may be referred to as a source, and the other may be referred to as a drain. This may be specifically determined based on a type of the thin film transistor 10.

The gate 2 includes a gate base 21 and a gate pillar 22, and the gate base 21 is in contact with the gate pillar 22. The gate base 21 is located on the first electrode 1, the gate pillar 22 is located between the gate base 21 and the first electrode 1, and there is a gap between the gate pillar 22 and the first electrode 1. Optionally, in a direction Z, the gate base 21 and the first electrode 1 are sequentially arranged, and an orthographic projection of the gate base 21 on a reference plane and an orthographic projection of the first electrode 1 on the reference plane at least partially overlap. The gate pillar 22 extends in the direction Z, the gate pillar 22 is strip-shaped, and the gate pillar 22 extends into the thin film transistor 10. The gate 2 is disposed in a T shape as a whole. The reference plane is perpendicular to the direction Z.

For example, the gate base 21 and the gate pillar 22 are of an integrated structure, in other words, the gate base 21 and the gate pillar 22 may be formed in a same patterning process. For another example, the gate base 21 and the gate pillar 22 are separately manufactured.

The gate dielectric layer 3 is located between the first electrode 1 and the gate pillar 22, to space the first electrode 1 from the gate pillar 22, thereby implementing electrical insulation between the first electrode 1 and the gate 2. The gate dielectric layer 3 is further in contact with a side surface of the gate pillar 22. For example, a sectional view of the gate dielectric layer 3 is U-shaped. Further, as shown in FIG. 3 and FIG. 4, there is a corner part at the top of the gate dielectric layer 3, and the corner part is in contact with a surface of a side that is of the gate base 21 and that is close to the first electrode 1.

The channel layer 4 is at least partially located between the first electrode 1 and the gate base 21, and is located on a side that is of the gate dielectric layer 3 and that is away from the gate pillar 22. The gate dielectric layer 3 spaces the channel layer 4 from the gate pillar 22. As shown in FIG. 3 and FIG. 4, when there is the corner part at the top of the gate dielectric layer 3, the gate dielectric layer 3 further spaces the channel layer 4 from the gate base 21. Further, as shown in FIG. 6, there is a corner part at the top of the channel layer 4, and a side surface of the corner part of the channel layer 4 is flush with that of the corner part of the gate dielectric layer 3. In this way, in a process of manufacturing the channel layer 4 and the gate dielectric layer 3, the channel layer 4 and the gate dielectric layer 3 may be obtained through synchronous etching by using a same mask. This helps simplify a manufacturing process of the thin film transistor 10.

The second electrode 5 is located between the first electrode 1 and the gate base 21, and is located on a side that is of the channel layer 4 and that is away from the gate pillar 22. The channel layer 4 spaces the second electrode 5 from the gate dielectric layer 3. An insulation layer is disposed between the first electrode 1 and the second electrode 5, to space the first electrode 1 from the second electrode 5 and form electrical insulation.

Both the first electrode 1 and the second electrode 5 are in contact with the channel layer 4. Ohmic contact is formed between the first electrode 1 and the channel layer 4, and ohmic contact is formed between the second electrode 5 and the channel layer 4. Optionally, the first electrode 1 may be in direct contact with the channel layer 4, or may be in indirect contact with the channel layer 4 through another medium. The second electrode 5 may be in direct contact with the channel layer 4, or may be in indirect contact with the channel layer 4 through another medium.

For example, materials of the first electrode 1, the gate 2, and the second electrode 5 are all conductive materials, for example, metal materials. Optionally, a material of any one of the first electrode 1, the gate 2, and the second electrode 5 may be TiN (titanium nitride), Ti (titanium), Au (gold), W (tungsten), Mo (molybdenum), In—Ti—O (ITO), Al (aluminum), Cu (copper), Ru (ruthenium), Ag (silver), or any combination thereof.

For example, a material of the gate dielectric layer 3 is an insulating material. Optionally, the material of the gate dielectric layer 3 may be SiO₂ (silicon dioxide), Al₂O₃ (aluminum oxide), HfO₂ (hafnium dioxide), ZrO₂ (zirconia), TiO₂ (titanium dioxide), Y₂O₃ (yttrium trioxide), Si₃N₄ (silicon nitride), or any combination thereof. In addition, the gate dielectric layer 3 may be of a single-layer structure, or may be of a multi-layer stack structure. A material of the single-layer structure and a material of each layer in the multi-layer stack structure may be SiO₂, Al₂O₃, HfO₂, ZrO₂, TiO₂, Y₂O₃, Si₃N₄, or the like, or any combination thereof.

For example, a material of the channel layer 4 is an oxide semiconductor (OS) material. Optionally, the material of the channel layer 4 may be an amorphous metal oxide or another wide bandgap material. For example, the amorphous metal oxide may be IGZO (indium gallium zinc oxide).

For example, a material of another insulation layer in the thin film transistor 10 is, for example, SiO₂, Al₂O₃, Si₃N₄, or any combination thereof.

It may be understood that the first electrode 1 and the second electrode 5 are spaced from each other in the direction Z, and the first electrode 1 and the second electrode 5 are located at different layers. A current between the first electrode 1 and the second electrode 5 flows in the direction Z. Correspondingly, the channel layer 4 may be referred to as a vertical channel. In other words, the thin film transistor 10 provided in this embodiment of this application is a thin film transistor of a vertical structure. Compared with the transistor of the planar structure, the thin film transistor 10 provided in this embodiment of this application has a smaller orthographic projection area on the reference plane. This can reduce an area occupied by the thin film transistor 10 on the reference plane, and can increase area utilization. In addition, because the first electrode 1 and the second electrode 5 are located at the different layers, during routing, the manufacturing process can be simplified, and routing difficulty can be reduced.

Still refer to FIG. 3 and FIG. 4. The channel layer 4 has a first surface 4A and a second surface 4B, the first surface 4A is in contact with the first electrode 1 and the second electrode 5, and the second surface 4B is in contact with the gate dielectric layer 3. A conductivity of the channel layer 4 gradually is decreased in a direction from the first surface 4A to the second surface 4B. In other words, in the channel layer 4, a part closer to the first surface 4A has stronger conductive performance, and it is easier for a charge carrier to flow; and a part closer to the second surface 4B has weaker conductive performance, and it is more difficult for a charge carrier to flow.

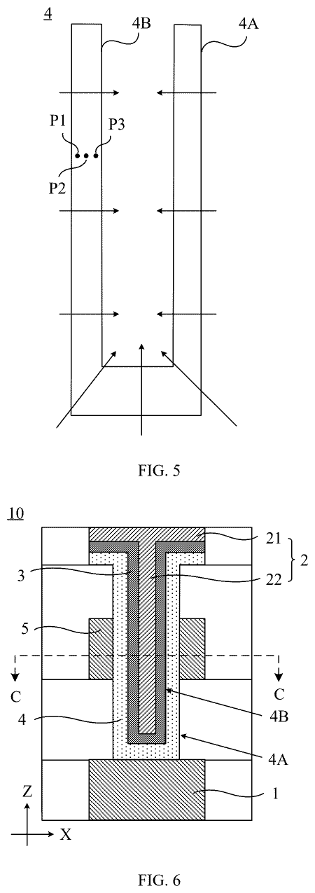

The channel layer 4 shown in FIG. 4 is used as an example. The first surface 4A is U-shaped, and the second surface 4B is U-shaped. The direction from the first surface 4A to the second surface 4B is, for example, a direction shown by each arrow in FIG. 5.

There are a plurality of change trends of the conductivity of the channel layer 4, and the change trend may be selectively set based on an actual requirement.

For example, the conductivity of the channel layer 4 is positively related to spacings between the second surface 4B and different locations of the channel layer 4. The conductivity of the channel layer 4 is linearly decreased in the direction from the first surface 4A to the second surface 4B. Three location points P1, P2, and P3 shown in FIG. 5 are used as an example. In the direction from the first surface 4A to the second surface 4B, conductivities of different location points of the channel layer 4 are different, a location point closer to the second surface 4B has a lower conductivity, and a location point farther away from the second surface 4B has a higher conductivity. In addition, a conductivity of a part of the channel layer 4 between different location points also varies. For example, a part of the channel layer 4 between the location point P1 and the location point P2 has a lower conductivity when being closer to the second surface 4B; and a part of the channel layer 4 between the location point P2 and the location point P3 has a lower conductivity when being closer to the second surface 4B.

For example, the conductivity of the channel layer 4 may change in a stepped manner. Three location points P1, P2, and P3 shown in FIG. 5 are used as an example. In the direction from the first surface 4A to the second surface 4B, a conductivity of a part of the channel layer 4 between the location point P1 and the location point P2 remains unchanged, a conductivity of a part of the channel layer 4 between the location point P2 and the location point P3 remains unchanged, and the conductivity of the part of the channel layer 4 between the location point P1 and the location point P2 is greater than the conductivity of the part of the channel layer 4 between the location point P2 and the location point P3. A conductivity of a part of the channel layer 4 between the location point P3 and the second surface 4B remains unchanged, and the conductivity of the part of the channel layer 4 between the location point P2 and the location point P3 is greater than the conductivity of the part of the channel layer 4 between the location point P3 and the second surface 4B.

The conductivity of the channel layer 4 is set, so that a part that is of the channel layer 4 and that is close to the first surface 4A has strong conductive performance. This can improve efficiency of injecting a charge carrier into the channel layer 4, reduce a contact resistance between the first electrode 1 and the channel layer 4, reduce a contact resistance between the second electrode 5 and the channel layer 4, and increase an on-state current (Ion) of the thin film transistor 10. In addition, a part that is of the channel layer 4 and that is close to the second surface 4B has low conductive performance. This can ensure that the channel layer 4 has a good semiconductor channel characteristic.

Therefore, the thin film transistor 10 provided in some embodiments of this application has a three-dimensional structure as a whole. The first electrode 1, the second electrode 5, and the gate base 21 of the gate 2 of the thin film transistor 10 are sequentially arranged in the direction Z (or referred to as a vertical direction), so that the gate pillar 22 of the gate 2 passes through the second electrode 5, and points to the first electrode 1. In addition, the gate dielectric layer 3 and the channel layer 4 are sequentially disposed between the gate pillar 22 and the first electrode 1 and between the gate pillar 22 and the second electrode 5, so that the thin film transistor 10 can form a thin film transistor of a vertical channel structure. The orthographic projection area of the thin film transistor 10 on the reference plane perpendicular to the direction Z is basically equal to an orthographic projection area of the first electrode 1 on the reference plane. Compared with the transistor of the planar structure, the thin film transistor 10 provided in this embodiment of this application has a smaller orthographic projection area on the reference plane. This can effectively increase area utilization of the thin film transistor 10.

In addition, the conductivity of the channel layer 4 is gradually decreased in the direction from the first surface 4A to the second surface 4B by setting the conductivity of the channel layer 4. This can effectively improve efficiency of injecting a charge carrier into the channel layer 4, reduce a contact resistance between the first electrode 1 and the channel layer 4, reduce a contact resistance between the second electrode 5 and the channel layer 4, and increase an on-state current of the thin film transistor 10.

In addition, when the thin film transistor 10 is used in the memory, not only an area occupied by the memory cell based on the thin film transistor 10 can be greatly reduced, a storage density can be greatly increased, but also a read/write speed of the memory cell based on the thin film transistor 10 can be increased.

It may be understood that, on the basis of ensuring that a variation of the contact resistance caused by setting the conductivity of the channel layer 4 is greater than a variation of the contact resistance caused by a size change of the thin film transistor 10, a size of the thin film transistor 10 may be further reduced, an area occupied by the thin film transistor 10 is further reduced, and a storage density of the memory is further increased.

In some embodiments, in the direction from the first surface 4A of the channel layer 4 to the second surface 4B of the channel layer 4, a work function of the channel layer 4 is gradually decreased, and/or an electron affinity of the channel layer 4 is gradually decreased. In other words, in a part that is of the channel layer 4 and that is closer to the first surface 4A, it is easier for the charge carrier to move from a conduction band minimum to a vacuum energy level (that is, it is easier for the charge carrier to escape), and in a part that is of the channel layer 4 and that is closer to the second surface 4B, it is more difficult for the charge carrier to move from the conduction band minimum to the vacuum energy level (that is, it is more difficult for the charge carrier to escape).

In the channel layer 4, a change trend of the work function, a change trend of the electron affinity, and a change trend of the conductivity are similar. For details, refer to the foregoing description of the change trend of the conductivity of the channel layer 4. Details are not described herein again.

The work function and/or the electron affinity of the channel layer 4 are/is set. This can improve the efficiency of injecting the charge carrier into the channel layer 4, reduce the contact resistance between the first electrode 1 and the channel layer 4, reduce the contact resistance between the second electrode 5 and the channel layer 4, increase the on-state current of the thin film transistor 10, and can further ensure that the channel layer 4 has the good semiconductor channel characteristic.

In some embodiments, the channel layer 4 is doped with a metal element, and a proportion of the metal element doped in the channel layer 4 is gradually decreased in the direction from the first surface 4A of the channel layer 4 to the second surface 4B of the channel layer 4.

It may be understood that conductivities, work functions, electron affinities, and the like at different locations in the channel layer 4 are related to the proportion of the doped metal element. A larger proportion of the doped metal element indicates a higher conductivity, a larger work function, a higher electron affinity, and the like of the channel layer 4. A smaller proportion of the doped metal element indicates a lower conductivity, a smaller work function, a lower electron affinity, and the like of the channel layer 4.

Proportions of metal elements doped at different locations in the channel layer 4 are modulated, so that conductivities, work functions, electron affinities, and the like at the different locations in the channel layer 4 can be adjusted. This can ensure that the conductivity of the channel layer 4 is gradually decreased in the direction from the first surface 4A of the channel layer to the second surface 4B of the channel layer, and can further ensure effect of increasing the contact resistance and the on-state current of the thin film transistor 10.

Optionally, the material of the channel layer 4 includes indium gallium zinc oxide, and the metal element doped in the channel layer 4 includes but is not limited to indium.

The gate dielectric layer 3, the channel layer 4, and the second electrode 5 may be disposed in a plurality of manners, and may be selectively disposed based on an actual requirement. With reference to accompanying drawings, the following schematically describes a manner of disposing the gate dielectric layer 3, the channel layer 4, and the second electrode 5. The manner of disposing the gate dielectric layer 3, the channel layer 4, and the second electrode 5 is not limited to the following illustration.

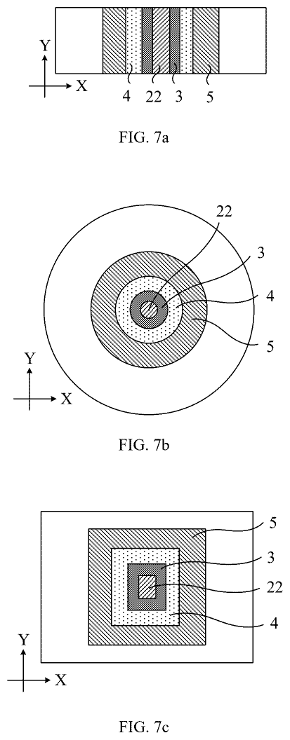

FIG. 6 shows a cross-sectional structure of a thin film transistor, and each of FIG. 7a to FIG. 7c shows a cross-sectional structure of the thin film transistor shown in FIG. 6 in a C-C direction.

In some embodiments, as shown in FIG. 7a, the gate dielectric layer 3 is located on two opposite sides of the gate pillar 22 in the direction X, the channel layer 4 is located on two opposite sides of the gate dielectric layer 3 in the direction X, and the second electrode 5 is located on two opposite sides of the channel layer 4 in the direction X.

In some other embodiments, as shown in FIG. 7b and FIG. 7c, a part that is of the gate dielectric layer 3 and that is located between the first electrode 1 and the gate base 21 surrounds the gate pillar 22. The channel layer 4 surrounds a part that is of the gate dielectric layer 3 and that is located between the first electrode 1 and the gate base 21. Correspondingly, the channel layer 4 surrounds the gate pillar 22. The second electrode 5 surrounds the channel layer 4. Cross-sectional shapes of the gate dielectric layer 3, the channel layer 4, and the second electrode 5 may be, for example, circular ring shapes shown in FIG. 7b or square ring shapes shown in FIG. 7c. In this case, the thin film transistor 10 may be referred to as a vertical channel-all-around thin film transistor (CAA TFT).

Disposing the gate dielectric layer 3, the channel layer 4, and the second electrode 5 in the foregoing manner is equivalent to increasing an effective channel width of the channel layer 4. This helps further increase an on-state current of the thin film transistor 10, and further increase a read/write speed of a memory cell based on the thin film transistor 10.

The channel layer 4 and the first electrode 1 may be disposed in a plurality of manners, and may be selectively disposed based on an actual requirement. The following schematically describes a manner of disposing the channel layer 4 and the first electrode 1 with reference to accompanying drawings. The manner of disposing the channel layer 4 and the first electrode 1 is not limited to the following illustration.

In some embodiments, as shown in FIG. 4 and FIG. 6, the channel layer 4 is further located between the first electrode 1 and the gate pillar 22, and is in contact with a surface of a side that is of the gate dielectric layer 3 and that is close to the first electrode 1.

A part that is of the channel layer 4 and that is located between the first electrode 1 and the gate pillar 22 is also in contact with the first electrode 1. Optionally, a sectional view of the channel layer 4 is U-shaped.

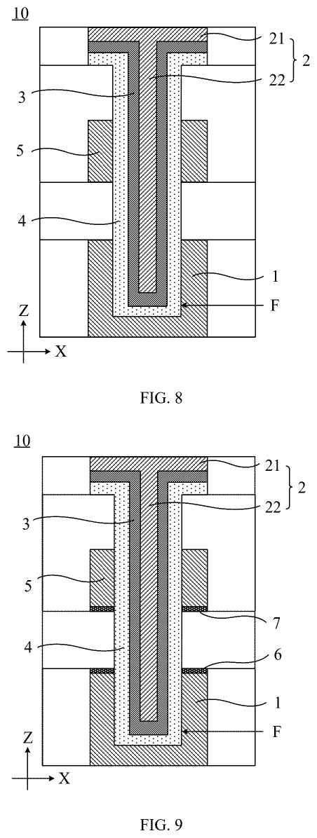

In some other embodiments, as shown in FIG. 3, FIG. 8, and FIG. 9, a groove F is disposed on a side that is of the first electrode 1 and that is close to the gate 2, and the channel layer 4 extends into the groove F.

A part that is of the channel layer 4 and that extends into the groove F is in contact with a side wall of the groove F, that is, in contact with the first electrode 1. Optionally, the sectional view of the channel layer 4 is two strips shown in FIG. 3. Alternatively, the sectional view of the channel layer 4 is, for example, similar to a U shape shown in FIG. 8. In other words, the channel layer 4 is also in contact with the surface of the side that is of the gate dielectric layer 3 and that is close to the first electrode 1.

In this embodiment, further, a depth of the groove F is large. As shown in FIG. 8 and FIG. 9, the gate dielectric layer 3 and the gate pillar 22 also extend into the groove F.

The channel layer 4 and the first electrode 1 are disposed in the foregoing manner. This helps increase a contact area between the first electrode 1 and the channel layer 4, and helps further reduce a contact resistance between the first electrode 1 and the channel layer 4.

The channel layer 4 has a plurality of structures, and the structure may be selectively disposed based on an actual requirement. The following schematically describes a structure of the channel layer 4 with reference to accompanying drawings. The structure of the channel layer 4 is not limited to the following illumination.

In some embodiments, the channel layer 4 is of a single-layer structure. Due to a conductivity design of the channel layer 4, the channel layer 4 is of a tapered structure.

This helps reduce complexity of the structure of the thin film transistor 10 and simplify a manufacturing process of the thin film transistor 10.

In a process of manufacturing and forming the channel layer 4 of the tapered structure, doping amounts of different target materials may be modulated, to gradually reduce a conductivity of the channel layer 4 in the direction from the first surface 4A of the channel layer 4 to the second surface 4B of the channel layer 4. For example, a material of the channel layer 4 is IGZO. For example, a doping amount of indium in the channel layer 4 is modulated in the direction from the first surface 4A of the channel layer 4 to the second surface 4B of the channel layer 4, so that the doping amount of the indium (or a proportion of the indium element) is gradually decreased. In this way, the conductivity of the channel layer 4 is gradually decreased.

In some other embodiments, the channel layer 4 is of a multi-layer stack structure. Optionally, the channel layer 4 is formed by stacking two films, three films, or even more films.

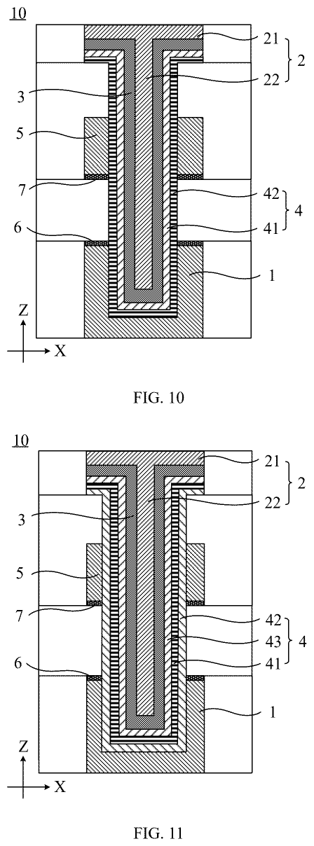

In some examples, the channel layer 4 is formed by stacking two films. As shown in FIG. 10, the channel layer 4 includes a primary channel layer 41 and a back channel layer 42. The primary channel layer 41 and the back channel layer 42 are sequentially stacked in a direction away from the gate pillar 22. In other words, the primary channel layer 41 is closer to the gate pillar 22, and the back channel layer 42 is closer to the first electrode 1 and the second electrode 5. For example, the back channel layer 42 is in contact with the first electrode 1 and the second electrode 5. A conductivity of the primary channel layer 41 is less than a conductivity of the back channel layer 42.

A material of the back channel layer 42 is, for example, IGZO or another oxide semiconductor material with a high conductivity, and a material of the primary channel layer 41 is, for example, IGZO or another oxide semiconductor material with a low conductivity.

In this embodiment of this application, the back channel layer 42 may be used as a primary film for charge carrier transmission, and the back channel layer 42 may be used to reduce a contact resistance between the channel layer 4 and the first electrode 1 and a contact resistance between the channel layer 4 and the second electrode 5, and increase the on-state current of the thin film transistor 10. In addition, the primary channel layer 41 may be used as a secondary film for charge carrier transmission, and the primary channel layer 41 is used to ensure a semiconductor channel characteristic of the channel layer 4.

For example, conductivities at different locations of the primary channel layer 41 are the same or approximately the same, in other words, the primary channel layer 41 is a film with a uniform conductivity. Conductivities at different locations of the back channel layer 42 are the same or approximately the same, in other words, the back channel layer 42 is a film with a uniform conductivity.

For example, a work function of the primary channel layer 41 is less than a work function of the back channel layer 42; and/or an electron affinity of the primary channel layer 41 is less than an electron affinity of the back channel layer 42.

This can ensure that concentration of a charge carrier in the back channel layer 42 is greater than concentration of a charge carrier in the primary channel layer 41, to ensure reduction of a contact resistance between the back channel layer 42 and the first electrode 1 and a contact resistance between the back channel layer 42 and the second electrode 5 and increase of the on-state current of the thin film transistor 10.

For example, each of the primary channel layer 41 and the back channel layer 42 is doped with a metal element. A proportion of the metal element doped in the primary channel layer 41 is less than a proportion of the metal element doped in the back channel layer 42. The metal element doped in the primary channel layer 41 is used to adjust the conductivity, the work function, the electron affinity, and the like of the primary channel layer 41; and the metal element doped in the back channel layer 42 is used to adjust the conductivity, the work function, the electron affinity, and the like of the back channel layer 42. The metal element doped in the primary channel layer 41 may be the same as or different from the metal element doped in the back channel layer 42.

Optionally, the material of each of the primary channel layer 41 and the back channel layer 42 includes indium gallium zinc oxide, and the metal element doped in each of the primary channel layer 41 and the back channel layer 42 includes indium.

The proportions of the metal elements in the primary channel layer 41 and the back channel layer 42 are modulated, so that the proportion of the metal element doped in the primary channel layer 41 is less than the proportion of the metal element doped in the back channel layer 42. This can ensure that the conductivity of the primary channel layer 41 is less than the conductivity of the back channel layer 42, that the work function of the primary channel layer 41 is less than the work function of the back channel layer 42, and/or that the electron affinity of the primary channel layer 41 is less than the electron affinity of the back channel layer 42, thereby ensuring effect of increasing the contact resistance and the on-state current of the thin film transistor 10.

In some other examples, the channel layer 4 is formed by stacking three films. As shown in FIG. 11, the channel layer 4 includes the primary channel layer 41, the back channel layer 42, and an interface layer 43. The primary channel layer 41 is located between the back channel layer 42 and the interface layer 43. The interface layer 43 is located between the gate pillar 22 and the primary channel layer 41, and is in contact with the gate dielectric layer 3.

For descriptions of the primary channel layer 41 and the back channel layer 42, refer to the descriptions in some of the foregoing examples. Details are not described herein again.

For example, a conductivity of the interface layer 43 is less than a conductivity of the primary channel layer 41.

This can further reduce conductive performance of the film in contact with the gate dielectric layer 3, to further ensure a semiconductor channel characteristic of the channel layer 4.

For example, a work function of the interface layer 43 is less than a work function of the primary channel layer 41; and/or an electron affinity of the interface layer 43 is less than an electron affinity of the primary channel layer 41.

In this way, the interface layer 43 may be used to push the charge carrier in the channel layer 4 away from a side surface that is of the interface layer 43 and that is in contact with the gate dielectric layer 3, to reduce a scattering probability of the charge carrier, increase effective mobility of the thin film transistor 10, and increase an on-state current of the thin film transistor 10. The interface layer 43 is disposed, so that a risk of scattering of the charge carrier can be effectively reduced when a size of the thin film transistor 10 is reduced and thicknesses of different films in the channel layer 4 are reduced.

For example, a Fermi level of the interface layer 43 is close to a Fermi level of the gate dielectric layer 3. A material of the interface layer 43 is, for example, a semiconductor material that has fewer defects and higher stability than that of the gate dielectric layer 3.

For example, the interface layer 43 is doped with a metal element. A proportion of the metal element doped in the interface layer 43 is less than a proportion of a metal element doped in the primary channel layer 41. The metal element doped in the interface layer 43 is used to adjust the conductivity, the work function, the electron affinity, and the like of the interface layer 43. The metal element doped in the interface layer 43 may be the same as or different from the metal element doped in the primary channel layer 41.

Optionally, the material of each of the interface layer 43 and the primary channel layer 41 includes indium gallium zinc oxide, and the metal element doped in each of the interface layer 43 and the primary channel layer 41 includes indium.

The proportions of the metal elements in the interface layer 43 and the primary channel layer 41 are modulated, so that the proportion of the metal element doped in the interface layer 43 is less than the proportion of the metal element doped in the primary channel layer 41. This can ensure that the conductivity of the interface layer 43 is less than the conductivity of the primary channel layer 41, that the work function of the interface layer 43 is less than the work function of the primary channel layer 41, and/or that the electron affinity of the interface layer 43 is less than the electron affinity of the primary channel layer 41, thereby ensuring effect of increasing the contact resistance and the on-state current of the thin film transistor 10.

In the foregoing embodiment, the channel layer 4 is formed by stacking a plurality of films, so that conductivities, work functions, electron affinities, and the like of different films can be more accurately controlled, and change trends of the conductivity, the work functions, the electron affinities, and the like at different locations of the channel layer 4 can be more accurately controlled through combined sorting of the different films, to help more accurately reduce the contact resistance and increase the on-state current of the thin film transistor 10.

In some possible embodiments, as shown in FIG. 9 to FIG. 11, the thin film transistor 10 further includes a first ohmic contact layer 6 and a second ohmic contact layer 7. The first ohmic contact layer 6 is located on a surface of a side that is of the first electrode 1 and that is close to the second electrode 5, and is in contact with the channel layer 4. The second ohmic contact layer 7 is located on a surface of a side that is of the second electrode 5 and that is close to the first electrode 1, and is in contact with the channel layer 4.

The first ohmic contact layer 6 is configured to reduce a contact resistance between the first electrode 1 and the channel layer 4, and the second ohmic contact layer 7 is configured to reduce a contact resistance between the second electrode 5 and the channel layer 4.

This helps improve performance of the thin film transistor 10 and increase an on-state current of the thin film transistor 10.

Optionally, materials of the first ohmic contact layer 6 and the second ohmic contact layer 7 are heavily doped IGZO or other oxide semiconductor materials. For example, the first electrode 1, the first ohmic contact layer 6, the gate dielectric layer 3, the second ohmic contact layer 7, and the second electrode 5 may form a metal-semiconductor-insulator-semiconductor-metal (MSISM) stack structure.

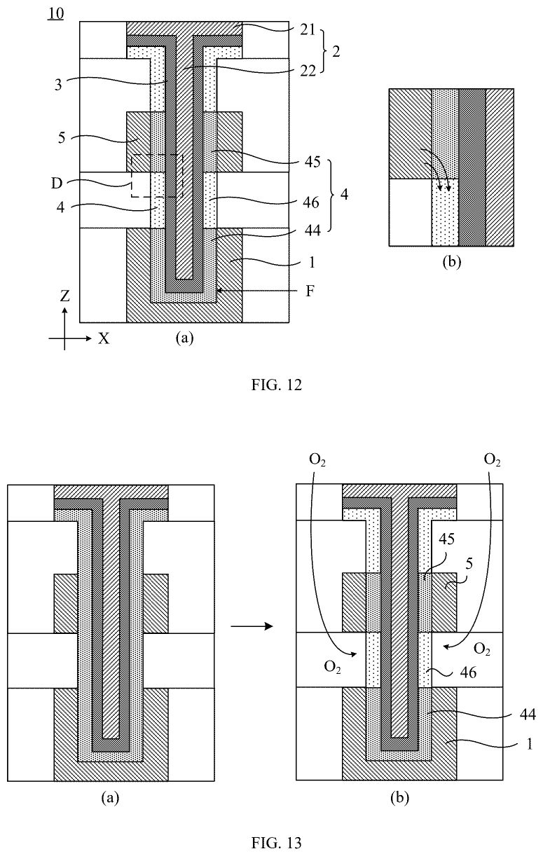

Some embodiments of this application further provide a thin film transistor. The thin film transistor may be an N-type transistor, or may be a P-type transistor. As shown in (a) in FIG. 12, the thin film transistor 10 includes a first electrode 1, a gate 2, a gate dielectric layer 3, a channel layer 4, and a second electrode 5. One of the first electrode 1 and the second electrode 5 may be referred to as a source, and the other may be referred to as a drain. This may be specifically determined based on a type of the thin film transistor 10.

The gate 2 includes a gate base 21 and a gate pillar 22 in contact with the gate base 21. The gate base 21 is located on the first electrode 1, and the gate pillar 22 is located between the gate base 21 and the first electrode 1. The gate dielectric layer 3 is located between the first electrode 1 and the gate pillar 22, and is in contact with a side surface of the gate pillar 22. The channel layer 4 is at least partially located between the first electrode 1 and the gate base 21, and is located on a side that is of the gate dielectric layer 3 and that is away from the gate pillar 22. A groove F is disposed on a side that is of the first electrode 1 and that is close to the gate 2, and the channel layer 4 extends into the groove F. The second electrode 5 is located between the first electrode 1 and the gate base 21, and is located on a side that is of the channel layer 4 and that is away from the gate pillar 22. Both the second electrode 5 and the first electrode 1 are in contact with the channel layer 4.

A structure of the gate 2, a manner of disposing the gate dielectric layer 3, the channel layer 4, and the second electrode 5, and a manner of disposing the channel layer 4 and the first electrode 1 are the same as those in the foregoing embodiment. For details, refer to the foregoing related descriptions. Details are not described herein again.

For example, as shown in FIG. 12, the channel layer 4 includes a first sub-part 44, a second sub-part 45, and a third sub-part 46. The first sub-part 44 is in contact with the first electrode 1, the second sub-part 45 is in contact with the second electrode 5, and the first sub-part 44 and the second sub-part 45 are located at two opposite ends of the third sub-part 46, and are both in contact with the third sub-part 46. In a direction X, the first electrode 1 covers the first sub-part 44, and the second electrode 5 covers the second sub-part 45.

Resistances of the first sub-part 44 and the second sub-part 45 are both less than a resistance of the third sub-part 46.

This can effectively reduce a contact resistance between the first electrode 1 and the channel layer 4, and reduce a contact resistance between the second electrode 5 and the channel layer 4, thereby increasing an on-state current of the thin film transistor 10. (b) in FIG. 12 is an enlarged view of a region D in (a) in FIG. 12. It can be seen that efficiency of injecting a charge carrier of the channel layer 4 from the second electrode 5 is high.

When the thin film transistor 10 is used in a memory, not only an area occupied by a memory cell based on the thin film transistor 10 can be greatly reduced, a storage density can be greatly increased, but also a read/write speed of the memory cell based on the thin film transistor 10 can be increased.

In some embodiments, the channel layer 4 is doped with hydrogen (H). Content of hydrogen in the first sub-part 44 and content of hydrogen in the second sub-part 45 are both greater than content of hydrogen in the third sub-part 46. Materials of the first sub-part 44 and the second sub-part 45 may also be referred to as a high-hydrogen oxide semiconductor material.

This can ensure that the resistances of the first sub-part 44 and the second sub-part 45 are both less than the resistance of the third sub-part 46, to ensure that there is a low contact resistance between the first electrode 1 and the channel layer 4, and ensure that there is a low contact resistance between the second electrode 5 and the channel layer 4.

Optionally, the channel layer 4 may be doped and repaired, to control resistances of different parts of the channel layer 4. For example, as shown in (a) in FIG. 13, after an initial thin film transistor is formed, an entire channel layer in the initial thin film transistor may be doped in a hydrogen treatment manner. Then, as shown in (b) in FIG. 13, the channel layer is repaired via oxygen (O₂). Because the first electrode 1 and the second electrode 5 cover and protect a part of the channel layer, the part of the channel layer is basically not repaired via oxygen, however, a part of the channel layer located between the first electrode 1 and the second electrode 5 is apparently repaired via oxygen, and most hydrogen in the part of the channel layer is removed. In this case, the first sub-part 44 that is covered by the first electrode 1 and that has a low resistance, the second sub-part 45 that is covered by the second electrode 5 and that has a low resistance, and the third sub-part 46 repaired via oxygen may be obtained. In this way, the entire channel layer is of a high-resistance structure in which a part in contact with the first electrode 1 and the second electrode 5 is a low-resistance channel region (that is, the third sub-part 46). The materials of the first sub-part 44 and the second sub-part 45 may also be referred to as the high-hydrogen oxide semiconductor material.

In some possible embodiments, the thin film transistor 10 further includes a first ohmic contact layer and a second ohmic contact layer. The first ohmic contact layer and the second ohmic contact layer are the same as those in the foregoing embodiments. For details, refer to the foregoing related descriptions. Details are not described herein again.

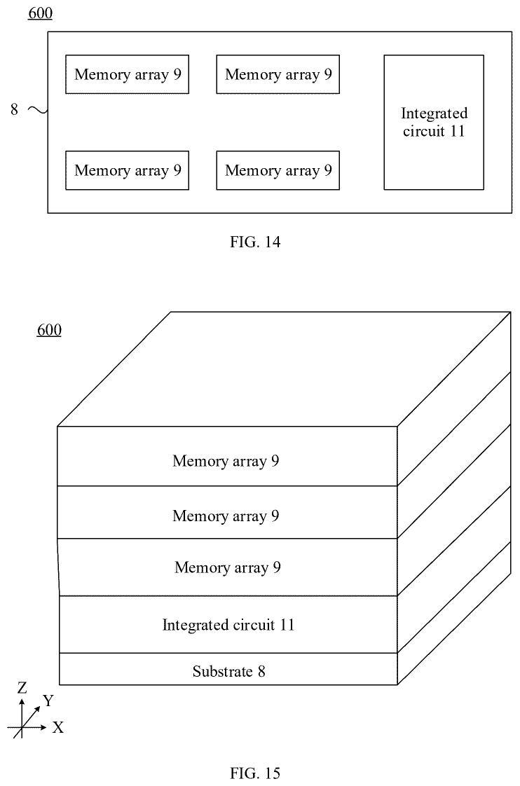

Each of FIG. 14 and FIG. 15 shows a structure of a memory. As shown in FIG. 14 and FIG. 15, the memory 600 includes a substrate 8 and memory arrays 9. The memory arrays 9 are located on the substrate 8.

For example, there are one, two, three, or even more layers of memory arrays 9. When there are two or more layers of memory arrays 9, the layers of memory arrays 9 are stacked in a direction Z as shown in FIG. 15, or the layers of memory arrays are tiled on the substrate 8 as shown in FIG. 14.

As shown in FIG. 14 and FIG. 15, the memory 600 further includes an integrated circuit 11. The integrated circuit 11 may be coupled to each layer of memory array 9 in the memory 600, and is configured to control each memory array 9 to store data. For example, the integrated circuit 11 may manage the data stored in the memory array 9, and communicate with an external device (for example, a host). For another example, the integrated circuit 11 may further control an operation of the memory array 9, for example, a read operation or a write operation. Certainly, the integrated circuit 11 may further perform any other proper function, and is not limited to the two examples.

Optionally, the integrated circuit 11 may be integrated on the substrate 8 by using a front end of line (FEOL) process, and the memory array 9 is integrated on the integrated circuit 11 by using a back end of line process. Certainly, the integrated circuit 11 and the memory array 9 may alternatively be independent of each other.

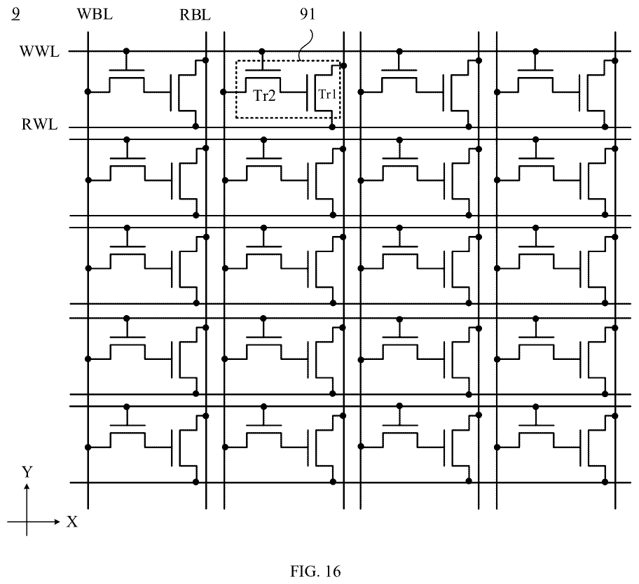

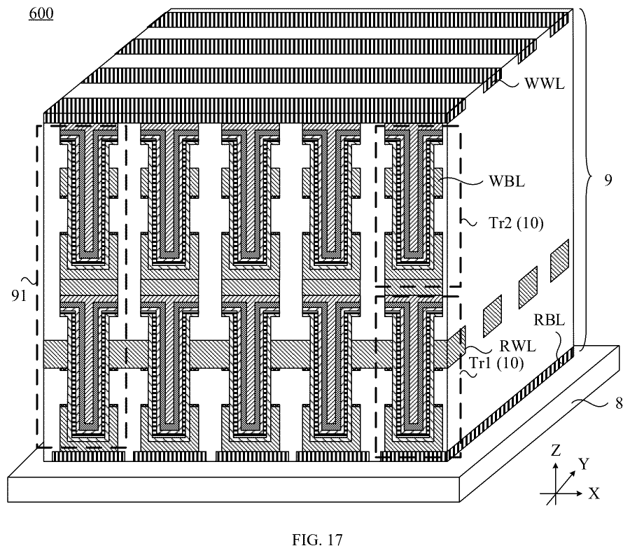

FIG. 16 shows an equivalent circuit of a memory array, and FIG. 17 shows a three-dimensional structure of a memory.

As shown in FIG. 16 and FIG. 17, the memory array 9 includes a plurality of memory cells 91, and the plurality of memory cells 91 are arranged, for example, in a plurality of rows and a plurality of columns. Each row of memory cells includes a plurality of memory cells 91 spaced from each other in a direction X, and each column of memory cells includes a plurality of memory cells 91 arranged in a direction Y. The memory array 9 further includes a plurality of write word lines WWL, a plurality of write bit lines WBL, a plurality of read word lines RWL, and a plurality of read bit lines RBL. The write word lines WWL extend in the direction X, and are spaced from each other in the direction Y. The write bit lines WBL extend in the direction Y, and are spaced from each other in the direction X. The read word lines RWL extend in the direction X, and are spaced from each other in the direction Y. The read bit lines RBL extend in the direction Y, and are spaced from each other in the direction X.

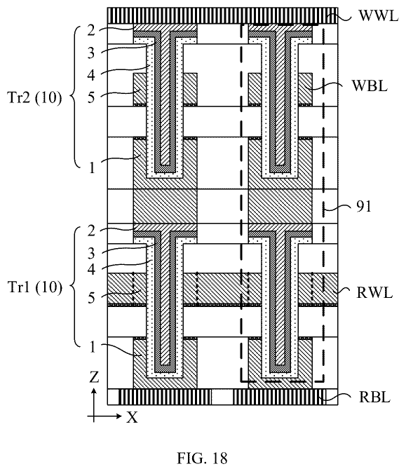

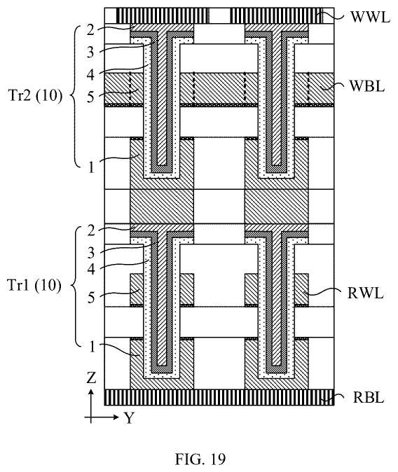

Each of FIG. 18 and FIG. 19 shows a cross-sectional structure of a memory array. With reference to FIG. 17 to FIG. 19, the memory cell 91 includes a first thin film transistor (which may also be referred to as a read transistor) Tr1 and a second thin film transistor (which may also be referred to as a write transistor) Tr2. The second thin film transistor Tr2 is located on the first thin film transistor Tr1. In other words, the second thin film transistor Tr2 and the first thin film transistor Tr1 are stacked in a direction Z, and the second thin film transistor Tr2 is located on a side that is of the first thin film transistor Tr1 and that is away from a substrate 8. A first electrode 1 of the first thin film transistor Tr1 is electrically connected to the read word line RWL, a second electrode 5 of the first thin film transistor Tr1 is electrically connected to the read bit line RBL, a gate 2 of the first thin film transistor Tr1 is electrically connected to a first electrode 1 of the second thin film transistor Tr2, a second electrode 5 of the second thin film transistor Tr2 is electrically connected to a write bit line WBL, and a gate 2 of the second thin film transistor Tr2 is electrically connected to the write word line WWL.

For an operating principle of the memory cell 91, refer to the foregoing descriptions. Details are not described herein again.

It may be understood that the memory cell 91 forms a 2T0C structure. In other words, the memory 600 provided in embodiments of this application is a gain cell memory based on the 2T0C structure.

In the memory cell 91, at least one of the first thin film transistor Tr1 and the second thin film transistor Tr2 may be the thin film transistor 10 described in any one of the foregoing embodiments. For example, the first thin film transistor Tr1 is the thin film transistor 10 in any one of the foregoing embodiments, or the second thin film transistor Tr2 is the thin film transistor 10 in any one of the foregoing embodiments, or each of the first thin film transistor Tr1 and the second thin film transistor Tr2 is the thin film transistor 10 in any one of the foregoing embodiments.

Optionally, structures of the first thin film transistor Tr1 and the second thin film transistor Tr2 may be the same or may be different. For example, as shown in FIG. 17, the first thin film transistor Tr1 and the second thin film transistor Tr2 have a same structure, and are the thin film transistor 10 shown in FIG. 11. For another example, as shown in FIG. 18, the first thin film transistor Tr1 and the second thin film transistor Tr2 have a same structure, and are the thin film transistor 10 shown in FIG. 9.

It may be understood that, because the thin film transistor 10 in any one of the foregoing embodiments is a thin film transistor of a vertical channel structure, an orthographic projection area of the thin film transistor on the substrate 8 is basically equal to an orthographic projection area of the first electrode 1 on a reference plane. In this way, an area, on the substrate 8, occupied by the memory cell 91 formed by the thin film transistor 10 in any one of the foregoing embodiments can be reduced. For example, an area of each memory cell may be reduced to 4F2. Further, a storage density of the memory 600 can be effectively increased.

In addition, because the thin film transistor 10 has a high on-state current, read/write speeds of the memory cell 91 and the memory 600 can be effectively increased.

Still refer to FIG. 18 and FIG. 19. In the direction X, second electrodes 5 of first thin film transistors Tr1 located in a same row may be connected together, to form one read word line RWL. In other words, the second electrodes 5 of the first thin film transistors Tr1 and the read word line RWL may be formed in a same patterning process. In the direction Y, second electrodes 5 of second thin film transistors Tr2 located in a same column may be connected together, to form one write bit line WBL. In other words, the second electrodes 5 of the second thin film transistors Tr2 and the write bit line WBL may be formed in a same patterning process. In this way, a manufacturing process of the memory 600 can be simplified, and routing difficulty of the memory 600 can be reduced.

The foregoing descriptions are merely specific implementations of this application, but are not intended to limit the protection scope of this application. Any variation or replacement readily figured out by a person skilled in the art within the technical scope disclosed in this disclosure shall fall within the protection scope of this application. Therefore, the protection scope of this application shall be subject to the protection scope of the claims.

1. A thin film transistor, wherein the thin film transistor comprises:
a first electrode;
a gate, comprising a gate base and a gate pillar in contact with the gate base, wherein the gate base is located on the first electrode, and the gate pillar is located between the gate base and the first electrode;
a gate dielectric layer, located between the first electrode and the gate pillar, and in contact with a side surface of the gate pillar;
a channel layer, at least partially located between the first electrode and the gate base, and located on a side that is of the gate dielectric layer and that is away from the gate pillar; and
a second electrode, located between the first electrode and the gate base, and located on a side that is of the channel layer and that is away from the gate pillar, wherein both the second electrode and the first electrode are in contact with the channel layer;
the channel layer has a first surface and a second surface, wherein the first surface is in contact with the first electrode and the second electrode, and the second surface is in contact with the gate dielectric layer; and
conductivities of the channel layer are gradually decreased in a direction from the first surface to the second surface.

2. The thin film transistor according to claim 1, wherein the channel layer is doped with a metal element, and a proportion of the metal element doped in the channel layer is gradually decreased in a direction from the first surface to the second surface.

3. The thin film transistor according to claim 2, wherein a material of the channel layer comprises indium gallium zinc oxide, and the metal element comprises indium.

4. The thin film transistor according to claim 1, wherein the channel layer comprises a primary channel layer and a back channel layer that are sequentially stacked in a direction away from the gate pillar; and
a conductivity of the primary channel layer is less than a conductivity of the back channel layer.

5. The thin film transistor according to claim 4, wherein each of the primary channel layer and the back channel layer is doped with a metal element; and
a proportion of the metal element doped in the primary channel layer is less than a proportion of the metal element doped in the back channel layer.

6. The thin film transistor according to claim 4, wherein the channel layer further comprises an interface layer located between the gate pillar and the primary channel layer; and
a conductivity of the interface layer is less than a conductivity of the primary channel layer.

7. The thin film transistor according to claim 6, wherein the interface layer is doped with a metal element; and
a proportion of the metal element doped in the interface layer is less than a proportion of a metal element doped in the primary channel layer.

8. The thin film transistor according to claim 6, wherein at least one of the following factors is satisfied:
a work function of the interface layer is less than a work function of the primary channel layer, or
an electron affinity of the interface layer is less than an electron affinity of the primary channel layer.

9. The thin film transistor according to claim 4, wherein at least one of the following factors is satisfied:
a work function of the primary channel layer is less than a work function of the back channel layer, or
an electron affinity of the primary channel layer is less than an electron affinity of the back channel layer.

10. The thin film transistor according to claim 1, wherein in a direction from the first surface to the second surface, at least one of the following factors is satisfied:
a work function of the channel layer is gradually decreased, or
an electron affinity of the channel layer is gradually decreased.

11. The thin film transistor according to claim 1, wherein the thin film transistor further comprises:
a first ohmic contact layer, located on a surface of a side of the first electrode, and in contact with the channel layer; and
a second ohmic contact layer, located on a surface of a side of the second electrode, and in contact with the channel layer.

12. The thin film transistor according to claim 1, wherein a part that is of the gate dielectric layer and that is located between the first electrode and the gate base surrounds the gate pillar, and the channel layer surrounds the gate pillar.

13. The thin film transistor according to claim 1, wherein the channel layer is further located between the first electrode and the gate pillar, and is in contact with a surface of a side of the gate dielectric layer.

14. The thin film transistor according to claim 1, wherein a groove is disposed on a side of the first electrode, and the channel layer extends into the groove.

15. A thin film transistor, wherein the thin film transistor comprises:
a first electrode;
a gate, comprising a gate base and a gate pillar in contact with the gate base, wherein the gate base is located on the first electrode, and the gate pillar is located between the gate base and the first electrode;
a gate dielectric layer, located between the first electrode and the gate pillar, and in contact with a side surface of the gate pillar;
a channel layer, at least partially located between the first electrode and the gate base, and located on a side that is of the gate dielectric layer and that is away from the gate pillar, wherein a groove is disposed on a side of the first electrode, and the channel layer extends into the groove; and
a second electrode, located between the first electrode and the gate base, and located on a side that is of the channel layer and that is away from the gate pillar, wherein both the second electrode and the first electrode are in contact with the channel layer; and
the channel layer comprises a first sub-part, a second sub-part, and a third sub-part, wherein the first sub-part is in contact with the first electrode, the second sub-part is in contact with the second electrode, and the first sub-part and the second sub-part are located at two opposite ends of the third sub-part, and the first sub-part and the second sub-part are both in contact with the third sub-part; and
resistances of the first sub-part and the second sub-part are both less than a resistance of the third sub-part.

16. The thin film transistor according to claim 15, wherein the channel layer is doped with hydrogen; and
content of hydrogen in the first sub-part and content of hydrogen in the second sub-part are both greater than content of hydrogen in the third sub-part.

17. The thin film transistor according to claim 16, wherein the thin film transistor further comprises:
a first ohmic contact layer, located on a surface of a side of the first electrode and in contact with the channel layer; and
a second ohmic contact layer, located on a surface of a side of the second electrode and in contact with the channel layer.

18. The thin film transistor according to claim 15, wherein a part that is of the gate dielectric layer and that is located between the first electrode and the gate base surrounds the gate pillar, and the channel layer surrounds the gate pillar.

19. The thin film transistor according to claim 15, wherein the channel layer is further located between the first electrode and the gate pillar, and is in contact with a surface of a side the gate dielectric layer.

20. A memory, wherein the memory comprises:
a substrate; and
at least one layer of memory array located on the substrate, wherein each layer of the memory array comprises a plurality of memory cells, a memory cell of the plurality of memory cells comprises a first thin film transistor and a second thin film transistor located on the first thin film transistor, and a gate of the first thin film transistor is electrically connected to a first electrode of the second thin film transistor; and
at least one of the first thin film transistor and the second thin film transistor is a thin film transistor;
wherein the thin film transistor, comprises:
first electrode;
gate, comprising a gate base and a gate pillar in contact with the gate base, wherein the gate base is located on the first electrode, and the gate pillar is located between the gate base and the first electrode;
a gate dielectric layer, located between the first electrode and the gate pillar, and in contact with a side surface of the gate pillar;
a channel layer, at least partially located between the first electrode and the gate base, and located on a side that is of the gate dielectric layer and that is away from the gate pillar; and
second electrode, located between the first electrode and the gate base, and located on a side that is of the channel layer and that is away from the gate pillar, wherein both the second electrode and the first electrode are in contact with the channel layer;
the channel layer has a first surface and a second surface, wherein the first surface is in contact with the first electrode and the second electrode, and the second surface is in contact with the gate dielectric layer; and
conductivities of the channel layer are gradually decreased in a direction from the first surface to the second surface;
or, wherein the thin film transistor, comprises:
first electrode;
gate, comprising a gate base and a gate pillar in contact with the gate base, wherein the gate base is located on the first electrode, and the gate pillar is located between the gate base and the first electrode;
a gate dielectric layer, located between the first electrode and the gate pillar, and in contact with a side surface of the gate pillar;
a channel layer, at least partially located between the first electrode and the gate base, and located on a side that is of the gate dielectric layer and that is away from the gate pillar, wherein a groove is disposed on a side the first electrode, and the channel layer extends into the groove; and
a second electrode, located between the first electrode and the gate base, and located on a side that is of the channel layer and that is away from the gate pillar, wherein both the second electrode and the first electrode are in contact with the channel layer; and
the channel layer comprises a first sub-part, a second sub-part, and a third sub-part, wherein the first sub-part is in contact with the first electrode, the second sub-part is in contact with the second electrode, and the first sub-part and the second sub-part are located at two opposite ends of the third sub-part, and the first sub-part and the second sub-part are both in contact with the third sub-part; and
resistances of the first sub-part and the second sub-part are both less than a resistance of the third sub-part.
